(19) United States
(12) Patent Application Publication
(10) Pub. No.: US 2026/0302719 A1
(43) Pub. Date: Oct. 1, 2026

(54) PACKAGE FOR RED-GREEN-BLUE LASER DIODES

(71) Applicant: Kyocera Corporation, Kyoto (JP)

(72) Inventors: Noritaka Niinou, Kyoto (JP); Eric Goutain, Fremont, CA (US); Oscar Romero, Tucson, AZ (US); Terry Towe, Tucson, AZ (US); Phillip Skahan, Goleta, CA (US)

(73) Assignee: Kyocera Corporation, Kyoto (JP)

(21) Appl. No.: 19/571,187

(22) Filed: Mar. 18, 2026

Related U.S. Application Data
(60) Provisional application No. 63/775,725, filed on Mar. 21, 2025.

(51) Int. Cl. H01S 5/023; H01S 5/024; H01S 5/40

(52) U.S. Cl. CPC H01S 5/023; H01S 5/4093; H01S 5/02469

(57) ABSTRACT

A metal, ceramic, or metal and ceramic package that provides housing, electrical connection, and/or thermal management for red-green-blue (RGB) laser diodes is described. The package may be thinned or may have an opening at an area where the RGB laser diodes are placed. The RGB laser diodes may be placed in an orientation that allows for separation from one another or may be oriented in parallel to one another. There may be single red, green, and blue lasers or there may be multiples of one or more laser colors. The lasers may be oriented so as to point toward a turning mirror and emanate upward out of the package or may be oriented to point out the side of the package. The lasers may point through a window, and a collimator, beam shaper, or other optical modulation component may be coupled to the window.

### CROSS-REFERENCE TO RELATED APPLICATIONS

This application claims priority to U.S. Provisional Application No. 63/775,725, filed Mar. 21, 2025, the entire contents of which are incorporated herein by reference for all purposes.

### TECHNICAL FIELD

The present disclosure relates generally to semiconductor packaging technology, and more specifically to packages for housing, electrically connecting, and thermally managing red, green, and blue (RGB) laser diodes.

### BACKGROUND

Display technologies have evolved significantly in recent years, with increasing demand for higher color accuracy, brightness, and efficiency in applications ranging from consumer electronics to large-scale projection systems. Among the various approaches, the use of RGB semiconductor laser diodes as light sources has gained prominence due to their ability to produce highly saturated colors and deliver precise wavelength control. These characteristics make RGB laser diodes particularly attractive for next-generation display systems, including laser televisions, digital projectors, and augmented reality devices, where color fidelity and luminous efficiency are critical performance metrics.

Despite these advantages, packaging RGB semiconductor laser diodes presents several technical challenges that have limited their widespread adoption in display applications. Traditional packaging solutions often utilize discrete housings for individual laser diodes, which can result in suboptimal thermal management, increased package size, and complicated optical alignment. In particular, prior art packages frequently suffer from inadequate heat dissipation, leading to reduced operational lifespans and diminished output power stability. Additionally, existing designs may lack the flexibility to accommodate multiple emitters, whether of the same or different colors, or to efficiently integrate optical components such as beam shapers, collimators, and mirrors necessary for directing and combining laser outputs. Electrical interconnection schemes in conventional packages are also frequently limited, failing to provide the compact, robust, and easily manufacturable solutions required for modern high-density display systems.

Accordingly, there is a clear need for advanced packaging solutions that address these deficiencies by enabling compact, thermally efficient, and optically precise integration of multiple RGB semiconductor laser diodes. Such solutions should facilitate versatile emitter arrangements, incorporate effective thermal management strategies, and support straightforward electrical and optical integration, thereby overcoming the limitations of prior techniques and advancing the performance and manufacturability of laser based display technologies.

### SUMMARY

Some embodiments described herein provide versatile packaging systems for RGB laser diodes that may be used for display applications. These systems feature metal, ceramic, or hybrid metal-ceramic housings that provide robust electrical connectivity and advanced thermal management. The package may be engineered to support various laser orientations—for example parallel or separated—to optimize optical output and heat dissipation, and may be configured to accommodate single or multiple emitters of each color. Some embodiments may include provisions for integrating optical components such as windows, collimators, beam shapers, and turning mirrors to precisely direct and modulate the laser light, as well as elements like heat spreaders, metal slug bases, and customizable ceramic layers for effective heat transfer and electrical interconnection. Some package architectures allow for flexible placement of lasers (at the edge, center, or within recesses), incorporate electrical pads and pathways for integrated control and power delivery, and support hermetic sealing for environmental protection. Collectively, these features address shortcomings of prior packaging solutions by enabling compact, efficient, and manufacturable integration of multiple RGB laser diodes with enhanced thermal, electrical, and optical performance suitable for high-quality laser based display systems.

In accordance with an embodiment, a light-emitting module includes a substrate; a first light-emitting element located on the substrate and having a first wavelength; a second light-emitting element located on the substrate and having a second wavelength longer than the first wavelength; and a third light-emitting element located on the substrate and having a third wavelength longer than the second wavelength, wherein the first light-emitting element is located on the substrate between the second light-emitting element and the third light-emitting element.

In an embodiment, the first light-emitting element and the second light-emitting element are each formed of a material containing nitrogen and gallium.

In another embodiment, a light-emitting surface of the third light-emitting element is positioned differently from a light-emitting surface of the first light-emitting element or the second light-emitting element in a light emission direction.

In another embodiment, a distance between the third light-emitting element and the first light-emitting element is greater than a distance between the first light-emitting element and the second light-emitting element.

In another embodiment, the third light-emitting element is longer than the first light-emitting element and the second light-emitting element.

In another embodiment, the first light-emitting element and the second light-emitting element further include an n-type semiconductor layer, an active layer, and a p-type semiconductor layer, and the p-type semiconductor layer is positioned closer to the substrate than the n-type semiconductor layer.

In another embodiment, the third light-emitting element further includes an n-type semiconductor layer, an active layer, and a p-type semiconductor layer, and the p-type semiconductor layer is positioned closer to the substrate than the n-type semiconductor layer.

In another embodiment, the third light-emitting element further includes an n-type semiconductor layer, an active layer, and a p-type semiconductor layer, and the n-type semiconductor layer is positioned closer to the substrate than the p-type semiconductor layer.

In another embodiment, the light-emitting module also includes a package having electrodes to which the substrate is fixed, wherein wire bonding directly connects the electrodes to n-type semiconductor layers of the first light-emitting element and the second light-emitting element.

In another embodiment, a thickness of the third light-emitting element is different from a thickness of the first light-emitting element or the second light-emitting element.

In another embodiment, the first light-emitting element, the second light-emitting element, and the third light-emitting element are respectively positioned on submount substrates, and thicknesses of the first light-emitting element, the second light-emitting element, and the third light-emitting element are smaller than a thickness of the submount substrates.

In another embodiment, light-emitting portions of the first light-emitting element, the second light-emitting element, and the third light-emitting element are located at different positions in a thickness direction.

In another embodiment, the first light-emitting element, the second light-emitting element, and the third light-emitting element are positioned on submount substrates, and the submount substrates have different thicknesses.

In another embodiment, dimensions along a light-emitting direction increase in order from the first light-emitting element, the second light-emitting element, to the third light-emitting element.

In another embodiment, the second light-emitting element or the third light-emitting element comprises a plurality of light-emitting elements. The plurality of the second light-emitting elements or the plurality of the third light-emitting elements may electrically connected in series with each other, and the first light-emitting element may be positioned between at least two of the plurality of the second light-emitting elements or the plurality of the third light-emitting elements.

In yet another embodiment, the light-emitting module also includes a base made of an electrically conductive material, on which the first light-emitting element, the second light-emitting element, and the third light-emitting element are disposed; and a package disposed around the base. In some embodiments, the base may be disposed below the package. In other embodiments, an upper surface of the base on which the first light-emitting element, the second light-emitting element, and the third light-emitting element are disposed is positioned higher than an upper surface of the package. In yet other embodiments, the light-emitting module may also include a lid member made of a light-transmissive material and disposed at an upper end of the package; and a lens member disposed above the lid member.

In accordance with another embodiment, a light-emitting module includes a substrate; a first light-emitting element located on the substrate and having a first wavelength; a second light-emitting element located on the substrate and having a second wavelength longer than the first wavelength; and a third light-emitting element located on the substrate and having a third wavelength longer than the second wavelength, wherein the first light-emitting element and the second light-emitting element further include an n-type semiconductor layer, an active layer, and a p-type semiconductor layer, and the p-type semiconductor layer is positioned closer to the substrate than the n-type semiconductor layer.

In accordance with yet another embodiment, a light-emitting module includes a substrate; a first light-emitting element located on the substrate and having a first wavelength; a second light-emitting element located on the substrate and having a second wavelength longer than the first wavelength; and a third light-emitting element located on the substrate and having a third wavelength longer than the second wavelength, wherein the first light-emitting element and the second light-emitting element are located on a first carrier, and the third light-emitting element is located on a second carrier different from the first carrier.

### BRIEF DESCRIPTION OF THE DRAWINGS

Exemplifying embodiments will now be described in more detail, with reference to the following appended drawings.

FIG. 1 provides a simplified top view depiction of an RGB package in accordance with some embodiments.

FIG. 2 is a simplified depiction of exemplary schemes for thermal management of an RGB package in accordance with some embodiments.

FIGS. 3a-3b provide simplified examples of RGB packaging wherein light is output to a waveguide in accordance with some embodiments.

FIGS. 4a-4b provide simplified 3-dimensional view and 2-dimensional views of exemplary packages with parallel-oriented lasers in accordance with some embodiments.

FIG. 5 is a simplified example of an RGB package with a ceramic base attached to a metal slug in accordance with some embodiments.

FIGS. 6a-6b provide a simplified example of an RGB package with a lid for hermetic sealing in accordance with some embodiments.

FIGS. 7a-7b provide a simplified example of another package structure in accordance with some embodiments.

FIGS. 8a-8b provide simplified examples of packages that may incorporate RGB lasers in accordance with some embodiments.

FIGS. 9a-9b provide simplified examples of packages with metal bases to facilitate heat transfer in accordance with some embodiments.

FIGS. 10a-10c provide simplified examples of packages that can hold RGB lasers in accordance with some embodiments.

FIGS. 11a-11b provide simplified top view depictions of RGB packages in accordance with some embodiments.

FIGS. 12a-12b provide simplified cross sectional depictions of RGB devices in accordance with some embodiments.

FIGS. 13a-13b provide simplified cross sectional depictions of RGB devices in accordance with some embodiments.

FIGS. 14a-14d provide simplified top view depictions of RGB packages in accordance with some embodiments.

As illustrated in the figures, the sizes of the elements and regions may be exaggerated for illustrative purposes and are provided to illustrate the general structures of the embodiments. Like reference numerals refer to like elements throughout.

### DESCRIPTION

This application relates to a package containing semiconductor diode RGB laser(s). In some configurations, this can enable displays to use laser light as the light and color source.

While there are many types of semiconductor diode lasers in red, green, and blue that may be used, an exemplary diode laser is a ridge-type Fabry-Perot laser diode. A ridge-type laser diode is formed using a substrate of material on which thin films for producing desired light emission may be fabricated. For light emission in blue or green wavelength range, the preferred substrate may be gallium and nitrogen-containing material (“GaN”). For light emission in red wavelength range, the preferred substrate may be gallium and arsenic-containing material (“GaAs”). For light emission in the red wavelength range, the substrate may be a material containing gallium and nitrogen (“GaN”). To create a laser diode, a plurality of layers of thin-film crystalline layers selected for forming a diode (e.g., with a quantum-well structure) are grown so as to cause a desired electron-hole recombination and photonic emission. For a GaN-based laser diode, in some configurations the thin films may be variations and combinations of gallium, nitrogen, indium, aluminum, and/or doping materials (e.g., phosphorous). For a GaAs-based laser diode, in some configurations the thin films may be variations and combinations of gallium, arsenic, indium, aluminum, and/or doping materials (e.g., phosphorous). The laser diode design typically uses a “quantum well” structure having several thin film layers of the materials in various compositions to result in a region having a junction wherein electrons and holes recombine to result in photonic emission. The photonic emission can be made coherent through the use of light-reflecting surfaces, which may be reflector coatings on facets on either end of the ridge structure, designed to enable light to exit out of one end and be contained by the other end. The facets may be cleaved or may be etched preferably using plasma reactive gas. In some configurations, a cleaved or etched facet without a coating can be used as a reflective surface.

Ridge laser diodes may be fabricated using epitaxial growth in combination with other process steps. Examples of types of laser diodes and manufacturing methods are described in the following patents and patent applications, the contents of which are incorporated by reference for all purposes:
“Manufacturable Laser Diode Formed on C-Plane Gallium and Nitrogen Material”, U.S. Pat. No. 11,569,637, filed Jan. 7, 2021;
“Manufacturable Laser Diode”, U.S. Pat. No. 9,379,525, filed Jun. 23, 2014;
“Manufacturable Gallium and Nitrogen Containing Single Frequency Laser Diode”, U.S. Pat. No. 12,464,802, filed Jun. 27, 2022;
“High Power Gallium and Nitrogen Containing Laser Diode Devices with a Modulation Device”, U.S. Publication No. 2025/0015558, filed Sep. 20, 2024;
“Improved Flip-and-Transfer Ridge Laser Diode Structure and Method”, U.S. Provisional Application No. 63/758,833, filed Feb. 14, 2025;
“Manufacturable RGB Laser Diode Source and System”, U.S. Pat. No. 11,710,944, filed Sep. 16, 2021.

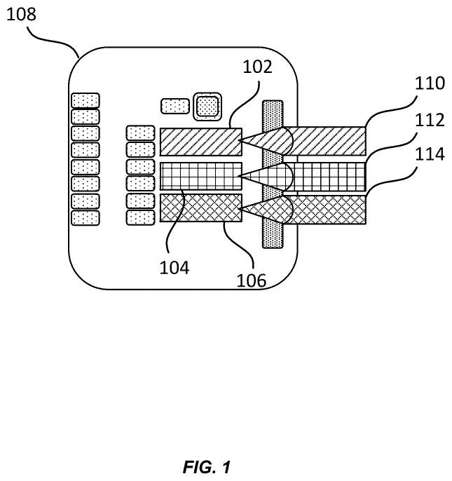

FIG. 1 provides a top view of a cartoon depiction of an embodiment of an RGB package. Individual red 102, green 104, and blue 106 ridge laser diodes may be incorporated into a package having a substrate surface 108 for laser attachment. One or more of the RGB lasers may include structures in addition to the basic laser waveguide for example to tighten the wavelength distribution and/or increase the light intensity. The RGB lasers may be arranged in order of wavelength, and they may also be arranged in the order of red, green, and blue. Wavelength stabilizers, modulators, or other features to control, modulate, or improve the wavelength quality may be included either as part of the ridge structure or as a separate but coupled component. The package can use a rectangular shape. For example, the package may be a square shape with equal dimensions on each side. In an embodiment, the package may be about 2-3 mm on each side and about 2-4 mm tall. The RGB lasers are shown to point in the same direction toward a common package side. The light emission 110, 112, 114 from each of the lasers exits out away from the package side. One or more of the laser emissions may go through a window and/or a beam shaping element such as a fast axis collimator that may be placed on the package so as to cause the modification of the light beam(s) before the light beam(s) exit the package. There may also be a plurality of electrical pads connected to the lasers as well as wirebonds or traces, to transmit and read electrical power and signals to and from each of the lasers, which items may be fabricated on the opposite side of the package from the light exit side. Additional components such as active or passive electrical, optical, or electro-optical components may be mounted in the package. Such additional components may include a photodiode for detecting light reflection and/or interfering light and enabling feedback and optimization of the laser light emission.

The RGB lasers are semiconductor laser diodes which may be ridge type side emitting Fabry Perot type, each having the capacity to emit light within a specified wavelength range for red, green, and blue individually. One or more of the RGB lasers may include structures fabricated thereon to tighten the wavelength distribution and/or increase the light intensity. One or more of the RGB lasers may include a feature integrated or external to modulate the wavelength to operate within a target wavelength specification. Notwithstanding wavelength augmentation or enhancements, none of the RGB lasers in the example of FIG. 1 include a color modifier. At least the blue and green laser may be fabricated using a flip-and-transfer process such that the individual laser chip is mounted on a carrier substrate which may be silicon carbide. The red laser may be fabricated using a flip-and-transfer process or may be fully fabricated on the starting point substrate. The flip-and-transfer process involves growing a semiconductor on a donor substrate (or the starting point substrate), removing the donor substrate, and then mounting the semiconductor layer onto a carrier substrate with the side opposite to the donor substrate facing downward. The RGB lasers may be positioned and attached to a submount so that the emission sides are facing one side of the package.

The RGB lasers point in the same direction so that the emission from each of the lasers exits the same side of the package. The laser emissions may go through a window and/or beam shaping element (fast axis collimator (FAC) for example) before exiting out of the package. The opposing end of the lasers may include a plurality of electrical pads connected to the lasers (wirebonds or traces) to transmit and read electrical power and signal to and from the RGB lasers. Additional components such as active or passive electrical or electro-optical components may also be mounted on the package submount.

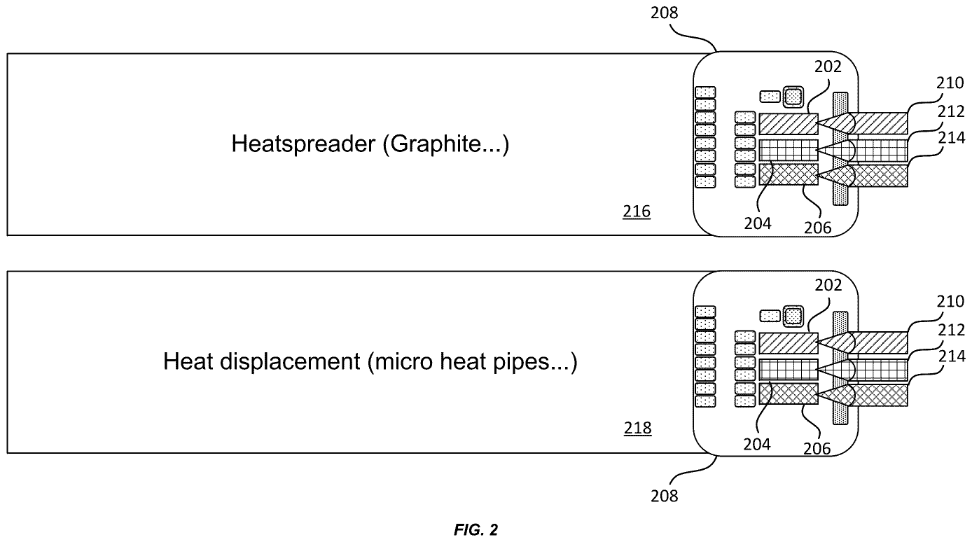

FIG. 2 is a cartoon depiction of exemplary schemes for thermal management of the package when the lasers are actively emitting light and thereby generating heat. Individual red 202, green 204, and blue 206 laser diodes may be incorporated into a package having a substrate surface 208 for laser attachment. Thermal management may include the use of a heat spreader made of thermally conductive material, such as graphite 216, that is directly attached to a package side. Another embodiment may include a heat displacement scheme such as micro heat pipes 218 or heat fins, also directly attached to a package side. The side of the package opposing the emission side may be attached to a heat spreader or heat pipes. A block of heat conductor formed into fins may also be used. Preferably, the thermal solution is combined with electrical ribbon to enable electrical connection to a power source as well as a light mixing or other receiving unit.

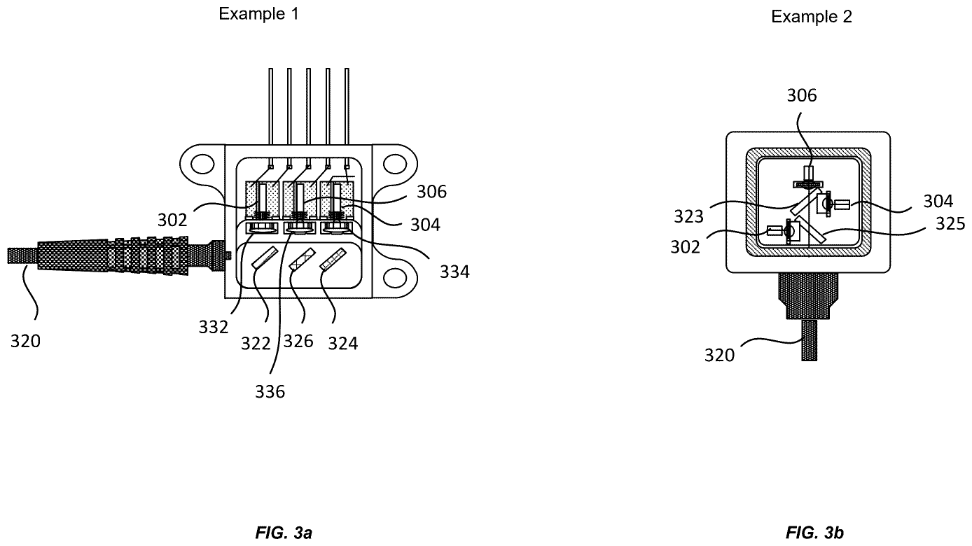

FIG. 3a is an example of RGB packaging, wherein the light outputs to a waveguide 320 such as a fiber waveguide. In example 1, the RGB lasers may be mounted in parallel on the package substrate surface but instead of the lasers being located near the side of the package, the lasers may be positioned closer to the center of the package and each of the lasers may point to a redirecting mirror either directly or through a beam shaper 332, 334, 336 such as a collimator and/or other optical elements for example to control wavelength. The beam shapers 332, 334, and 336 may each be arranged at the same distance from the respective light-emitting surfaces of the red laser 302, green laser 304, and blue laser 306, or at different distances. The lasers may each be electrically connected to a power source and driver. The electrical connections to the emitters may be positioned behind the emitters, on the opposite end from the emission. Each of the lasers may point to its own assigned mirror. Each mirror is angled so that the light reflects off the mirror toward the waveguide that is positioned at the package edge (e.g., the redirected optical axes are colinear with each other). In this example red laser 302 is aligned with mirror 322, blue laser 306 is aligned with mirror 326, and green laser 304 is aligned with mirror 324.

Example 2 in FIG. 3b provides another arrangement where the RGB lasers 302, 304, 306 are not parallel but rather distanced apart from one another and the light emission from each laser may go through a beam shaping optical element and propagate toward the waveguide or hit a mirror that is positioned in the package that redirects light out of the package and toward the waveguide 320. A benefit to non-parallel laser placement may be to create space so that each laser may have improved ability to dissipate heat while reducing the effects of thermal emission from an adjacent laser. An RGB package may also contain electrical connection which may be planar to the lasers such as pin through the package or placed on the bottom side of the package opposite the surface of the lasers.

In this example, instead of the RGB lasers being oriented parallel to each other, the RGB lasers may be oriented to each point toward a different side of the package. In this example, wherein the package has four sides, the blue laser 306 may point directly to the side having the externally-attached waveguide 320, and the green laser 304 may point to an adjacent package wall from the blue laser, and the red laser 302 may point to the opposite wall from the green laser so that each of the lasers is pointed toward a different wall. Those lasers that are not pointing toward the waveguide point into a deflecting mirror 323, 325 so that the emission can be angularly redirected toward the wall that includes the waveguide. Electrical connections (not shown) could be planar to the lasers (pin through the package) or place on the bottom of the submount (surface mount device (SMD) type).

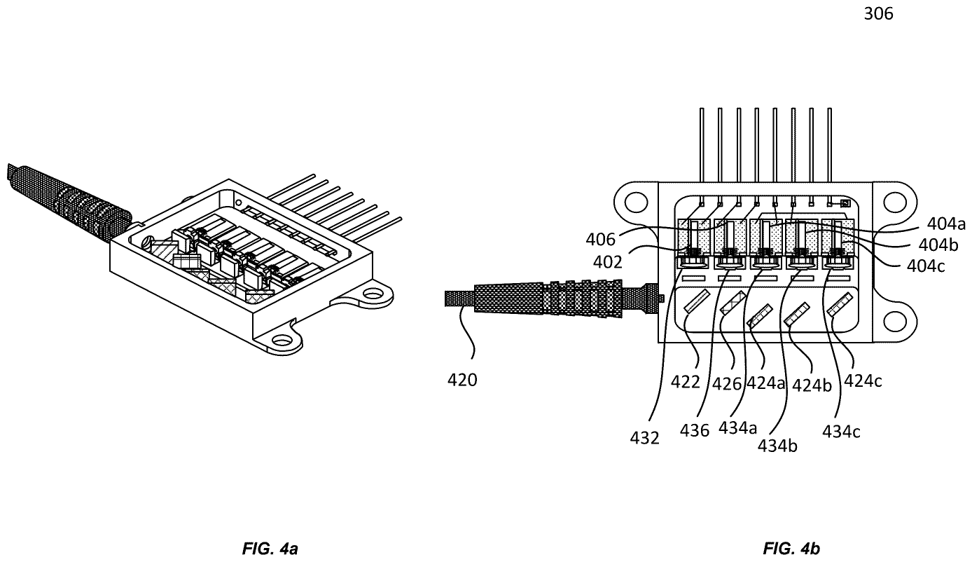

FIG. 4a is a 3-dimensional view and FIG. 4b is a 2-dimensional top view of an embodiment of a package with parallel-oriented lasers. The parallel orientation can be preferred if multiple emitters including multiple emitters of one color are desired. In the example shown, there is one red emitter 402, one blue emitter 406, and three green emitters 404a, 404b, 404c, which may be chosen to balance an emission power emanating from a given color. As an example, one of the colors may be provided as multiple lasers to provide an emission “boost” to be commensurate with the emission power characteristics of the other colors to reach and allow a wider color gamut. As shown in the example, each of the parallel-oriented lasers point the emission side to an associated optic 432, 436, 434a, 434b, 434c for beam shaping, collimation, or other purpose. Note that the optic 422 for the red laser 402 is shown to be further separated from the red emitter compared to the blue and green lasers because of differences in the red beam profile and other characteristics compared to blue and green lasers. Each laser light then exits the optic and emits to mirrors 422, 426, 424a, 424b, 424c that are placed and oriented so as to reflect the laser light toward a waveguide 420. Note that the mirrors for the multiple lasers of a color, in this example green, may be staggered in distance to achieve desired output beam characteristics with spatial combining. The waveguide receiving the output beams from each of the lasers may be coupled to a side of the package (e.g., to jut out a side of the package). Electrical connectors are placed in proximity with each of the parallel-oriented lasers. Electrical leads may be fabricated in the package to electrically connect each laser to one another and to power source(s) and drivers.

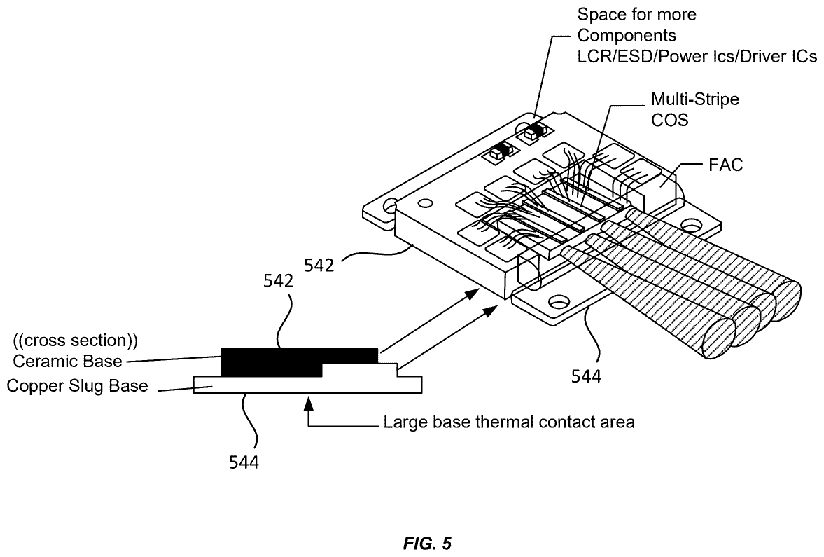

FIG. 5 is an example of an RGB package with parallel-laid lasers, wherein the package comprises a ceramic base 442 and a metal slug 444 to place the lasers for thermal management. The ceramic base 442 may be attached to the metal slug 444. A package may be disposed around the base, and/or the base may be disposed below the package. The metal slug may be rectangular shaped. The metal could be copper for example. The lasers may be attached to a metal surface on the ceramic base (e.g., using an interposer). The emitters are located at or near the edge of the package so that the light emission shines out the side. The metal slug base may form a lip out of one or two sides from the ceramic base, and the lip forms a frame and may include holes for attaching the package to a surface via screws. The extruded metal may have increased thickness in the section that supports the lasers, because the lasers will produce heat. Preferably, the metal slug base has a flat bottom with a first thickness sufficient to serve as a supporting base for the ceramic base. The ceramic base may be of various shapes but is shown as having a square or rectangular surface with a thickness sufficient to support layers that include electrical leads and pathways, wires, and pads. The top surface of the ceramic base may include electrical pads, wire bonds, and leads to electrically couple the lasers to a power supply as well as drivers. The ceramic base may include additional components for providing smart control of the lasers, power modulators, electrostatic discharge protection, sensor (which may be photodiode), and other components. On the ceramic base, an area that supports the lasers is shown as being thinner than the remainder of the ceramic base. In the thinner portion of the ceramic base where the lasers are located, there are no or minimal electrical leads that are fabricated between layers. There may be no ceramic layers directly underneath the platform holding the lasers. The ceramic base having a thinness at the location where the lasers are attached has the appearance of an extension when viewed from the side. The extension portion is attached to the metal slug base which itself includes a thickness to provide an attachment surface for the ceramic base extension. From the side, the metal slug base thickness may have the appearance of a lip, which may have sharp corners or may have rounded corners depending on the shape of the ceramic base extension. The metal slug base shape and the ceramic base bottom should preferably mate so as to maximize the heat dissipation from the ceramic base. The lasers may point light directly out of the package, or may emit through an optic, beam shaper, collimator or a window.

For applications where full hermeticity is not required, a ceramic surface-mount device (SMD) may be used, an example of which is shown in FIG. 5 in 3-D view. The ceramic SMD base may be rectangular shaped, with laser diodes (multi-stripe or discrete chip on submount (CoS)) attached in parallel on surface of the ceramic via an interposer. The emitters point out of the package, the light emission which may shine through a simple window or beam shaping optics such as a collimator which may be a fast-axis collimator (FAC) as shown. Wire bonds electrically connect the emitters to pads fabricated on the SMD. The SMD may include additional active or passive components. The SMD may have a bottom side with electrical pads to electrically connect the SMD to ground and power. The SMD may be surrounded by a frame for attaching onto another device. The frame may be made of metal for heat dissipation. The frame may be wrapped around the SMD, or may be a solid metallic slug for heat dissipation.

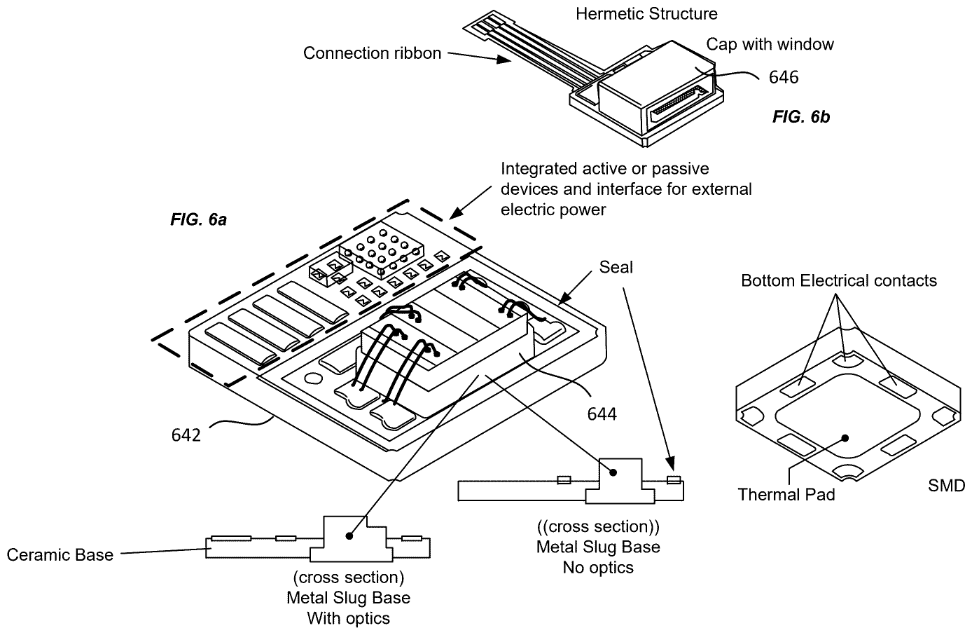

FIGS. 6a-6b provide an example of an RGB package that is designed to accommodate a lid for hermetic sealing. An embodiment of a package design with a ceramic base 642 is shown, wherein the ceramic base is provided as having a square or rectangular surface shape, with a flat bottom and a thickness sufficient to include layers having electrical pads, electrical leads, and wires. There may also be a hole in the ceramic base large enough to accommodate a platform insert on which the laser diodes may be attached. The platform insert may itself be a metal slug base 644 which from the side may have the appearance of a plug with a bottom portion being wider so as to anchor the metal slug base in place when placed through the hole opening in the ceramic base. The metal slug extrusion through the ceramic base is a thickness effective to dissipate heat with the thickness limits set by the protective cap to be placed thereon. The lasers are placed preferably in parallel to one another on the top surface of the metal slug base, and could use an interposer for attachment to the metal. The lasers may emit into a collimator or other optics. The portion containing the lasers jutting out of the top surface of the ceramic base may be a laser platform. The top surface may be higher than an upper surface of the package. Wires may be fabricated to provide electrical power and electrical controls to the lasers. Wire bond pads are fabricated on the ceramic base surface to the side of the laser platform. On the opposite end of the package from the lasers, there may be active or passive devices attached thereto. Also, there may be interfaces for external electric power. The electrical contacts maybe be on top or the bottom of the package. The interconnection to these contacts could be a ribbon (or a flexible printed circuit) and in addition of electrical could have a thermal dissipation function. If hermetic sealing is desired, a seal lip is placed on the ceramic base surrounding the laser platform and associated wire bond pads so as to form an outline. The seal lip may accommodate a bonding material sufficient to secure a hermetic cap 646 placed on the seal lip. The hermetic cap may include a window and/or beam shaping optics positioned to allow emission from the parallel-oriented lasers to emit through and out of the package. In an embodiment, beam shaping optics sealed in the cap may be a collimator such as a fast axis collimator, and/or may include alternative optics. A material of the window may use a light-transmittable material such as glass or sapphire.

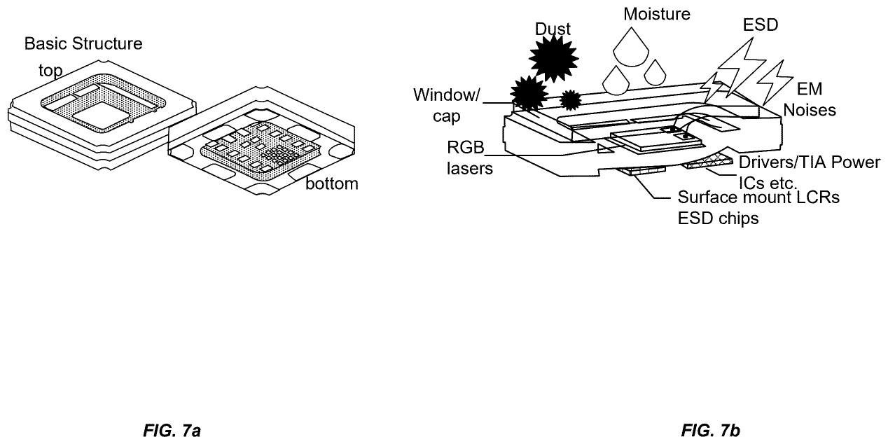

FIGS. 7a-7b provide more information about an embodiment of another package structure. There may be multiple layers with electrical pads and leads running within the package and between the layers according to the electrical requirements of the packaged laser diodes. The bottom of the package may have electrical pads for electrical attachment to an electrical board and may further include additional active or passive components such as electro-static discharge protection chips, drivers, power chips, converters, resistors and other components. The top side of the package may be flat or may include recesses with levels defined by one or more stair-steps that include electrical leads.

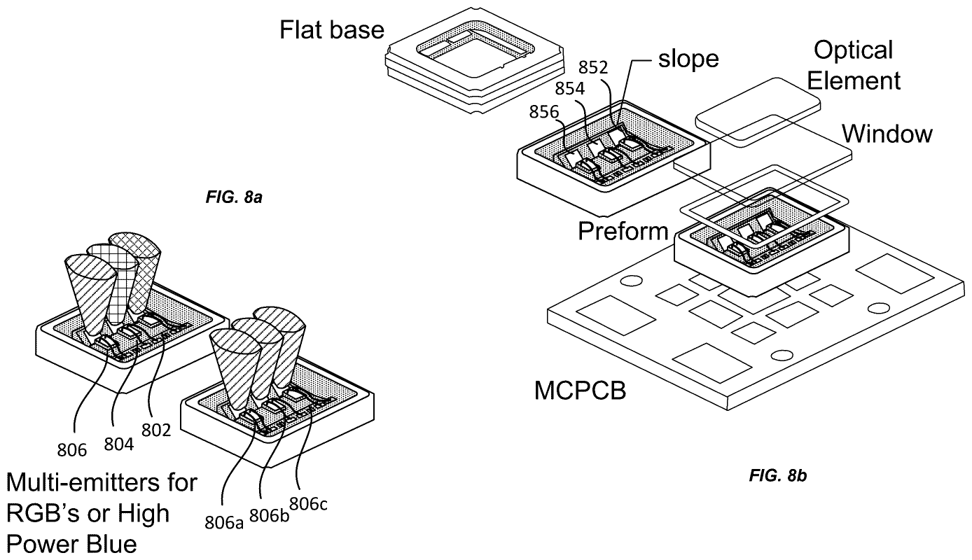

FIGS. 8a-8b provide an example of how the package of FIG. 7 may incorporate RGB lasers. Unlike the examples shown at FIGS. 1 through 6, wherein the lasers are placed on the package surface adjacent to an edge of the package so that light emission emanates from an edge of the package, in the example of FIG. 8, the RGB lasers 802, 804, 806 are placed in the center of the package, within the package recess. The RGB laser diodes may be attached to an interposer for heat dissipation and/or pre-alignment. The RGB lasers may be arranged in parallel, with each emitter pointing to a dedicated turning mirror 852, 854, 856 that is angled so as to turn the light emission to 90 degree or other angle, to enable the light emission to emanate upward out of the package. The turning mirror 852, 854, 856 may each be implemented using, for example, a prism having a triangular column shape; however, the configuration is not limited thereto. Alternatively, a single prism having a triangular column shape may be used as the turning mirror 852, 854, 856. In this case, laser beams respectively emitted from the RGB lasers 802, 804, 806 are reflected by the single prism. The width of the single prism may be greater than the distance between the emitted light beams of the two lasers positioned at opposite ends among the RGB lasers, and may be smaller than the overall width of the RGB lasers, including the carrier substrate. Note that in this example, the lasers do not need to be RGB lasers. The lasers may be multi-emitter type of the same light (e.g., blue lasers 806a, 806b, 806c) for higher aggregate power. There may be a window covering the entire package or covering the recess portion that holds the lasers. There may be an optical element above or below the window depending on design preferences. The window may be sealed on the package against a preform edge lip. The package may be attached to a multi-chip printed circuit board (MCPCB) and a heat sink.

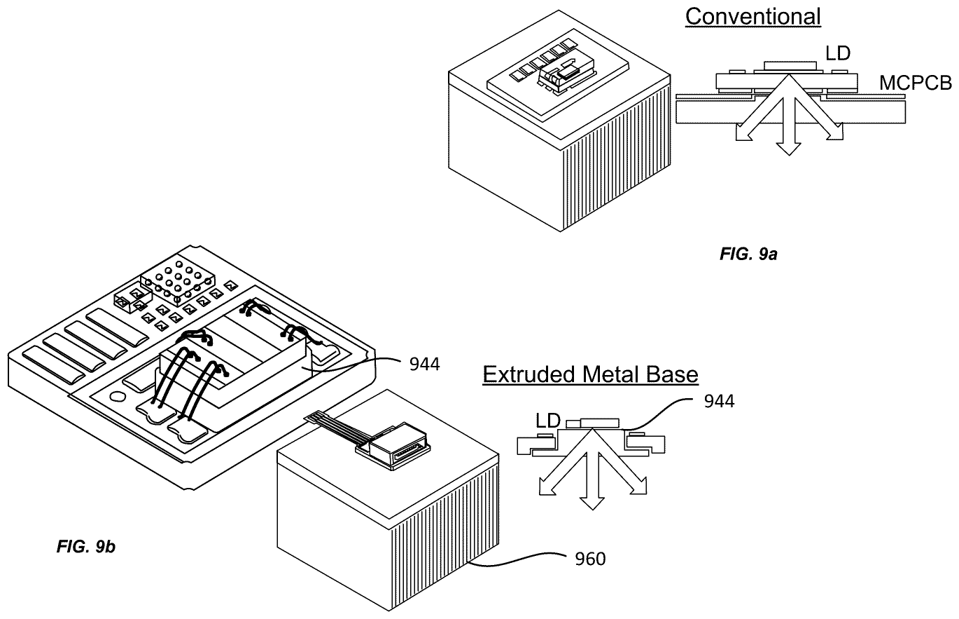

FIGS. 9a-9b provide a diagrammatic depiction of an embodiment of how the extruded metal base 944 facilitates heat transfer. The extruded metal base is a result of placing a ceramic base around a slug of copper and extruding a portion of the copper through the ceramic base. Using the example of the package shown at FIG. 6, the extruded metal base forms a thickness that serves as a platform on which the RGB laser diodes are placed. The thickness of the metal slug provides heat dissipation paths which in turn may dissipate through an underlying heat transfer surface such as a surface with heat fins 960 or to a MCPCB for dual electrical and thermal functions. The metal base is not limited to copper and may be composed of a material with a higher thermal conductivity than the RGB laser diode. In some configurations, the extruded metal base may be coupled directly to a heat dissipator which may be a slug heat fin or may be coupled to a metal-core printed circuit board so as to dually dissipate heat and provide electrical functionality.

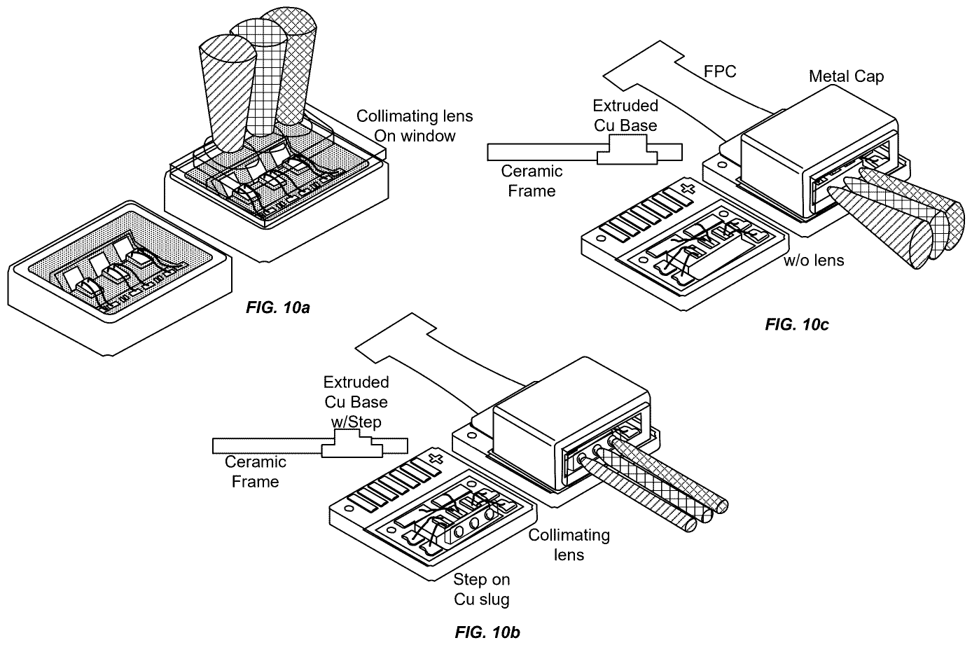

FIGS. 10a-10c provide example options for a package with a ceramic base that can hold RGB lasers. In FIG. 10a there is the FIG. 8-style of package with a recess inside which RGB layers are placed and pointing toward individual turning mirrors. The mirrors are not limited to being individual mirrors, and, for example, a single large common mirror may be used. The single large common mirror may be a single prism. The turning mirrors cause the light emission to be angled upward away from the ceramic package. The upward-angled lasers may emit through a protective window (or lid member) of a light-transmissive material on which a collimating lens may be placed so as to provide collimated laser light out through the top of the package. In the examples of FIGS. 10b-10c, there may be a rectangular or square package with an opening through which an extruded metal base may extend. The extruded metal base may include a step (FIG. 10b) or may not include a step (FIG. 10c). The top of the extruded metal base serves as a platform on which RGB lasers are mounted, preferably in parallel to one another and pointed to emit out the side of the package. There may be a protective cap on the laser platform with a window and optics attached thereto so as to provide optically modified laser light out the side. The extruded metal base design reserves space on the ceramic base to allow for placement of electrical leads to facilitate external power supply. The ceramic base also includes space for active and passive components including electrostatic discharge protection, driver chips, power converters, and if desired, one or more photodetectors to set up for feedback. The ceramic base also includes electrical pads, landings, leads, and wires to provide for electrical integration of the lasers and components.

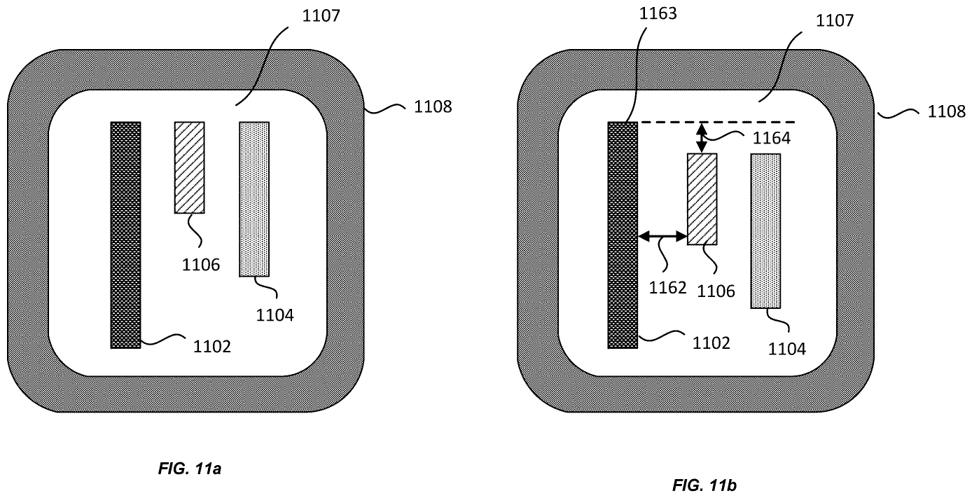

FIGS. 11a-11b provide simplified top view depictions of RGB packages in accordance with some embodiments. FIG. 11a shows a light emitting module 1108 with a first light-emitting element 1106 having a first wavelength located on a substrate 1107, a second light-emitting element 1104 having a second wavelength longer than the first wavelength located on the substrate 1107, and a third light-emitting element 1102 having a third wavelength longer than the second wavelength located on the substrate 1107. The first light-emitting element 1106 is positioned between the second light-emitting element 1104 and the third light-emitting element 1102.

The first light-emitting element 1106 has the shortest wavelength and typically generates less heat than the other light-emitting elements that have longer wavelengths. The arrangement illustrated in FIG. 11a can reduce thermal effects of the first light-emitting element 1106 on the second light-emitting element 1104 and the third light-emitting element 1102.

In some embodiments, the third light-emitting element 1102 may be longer than the first light-emitting element 1106 and the second light-emitting element 1104 as illustrated in this example.

FIG. 11b illustrates an embodiment where a light-emitting surface 1163 of the third light-emitting element 1102 is positioned differently than light emitting surfaces of the first light-emitting element 1106 and the second light-emitting element 1104. Specifically, the light-emitting surface 1163 of the third light-emitting element 1102 is positioned closer to an edge of the substrate 1107 by a distance 1164. In this example, all of the light-emitting elements may emit light in the same direction (upward in the drawing).

FIG. 11b also illustrates that in some embodiments a distance 1162 between the third light-emitting element 1102 and the first light-emitting element 1106 may be greater than a distance between the first light-emitting element 1106 and the second light-emitting element 1104.

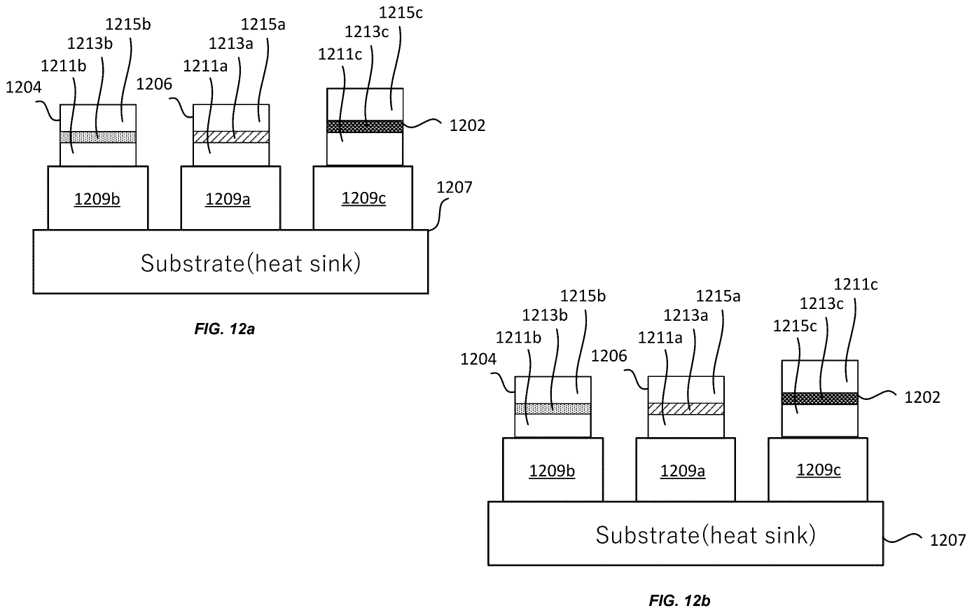

FIGS. 12a-12b provide simplified cross sectional depictions of RGB devices in accordance with some embodiments. FIG. 12a shows an example where a first light emitting element 1206 and a second light emitting element 1204 each include n-type semiconductor layers 1215a, 1215b, active layers 1213a, 1213b, and p-type semiconductor layers 1211a, 1211b. The p-type semiconductor layers 1211a, 1211b are positioned closer to substrate 1207 than the n-type semiconductor layers 1215a, 1215b. Note that in is example the light emitting elements are coupled to submounts 1209a-1209c. In other embodiments, the submounts may be omitted and the light-emitting elements may be coupled to the substrate 1207. Electrodes may be formed on substrate 1207, and wirebonding may connect the electrodes to the n-type semiconductor layers 1215a, 1215b.

In the example of FIG. 12a, the third light-emitting element 1202 also includes an n-type semiconductor layer 1215c, an active layer 1213c, and a p-type semiconductor layer 1211c, and the p-type semiconductor layer 1211c is also positioned closer to the substrate 1207 than the n-type semiconductor layer 1215c.

FIG. 12b is similar to FIG. 12a except the n-type semiconductor layer 1215c of the third light-emitting element 1202 is positioned closer to the substrate 1207 than the p-type semiconductor layer 1211c.

In some embodiments, a thickness (height in FIGS. 12a-12b) of the third light-emitting element 1202 is different than a thickness of the first light-emitting element 1206 and the second light-emitting element 1204 as shown in these examples. Also, in some embodiments where the light emitting elements are positioned on submounts 1209a-1209c, a thickness (height in FIGS. 12a-12b) of the first light-emitting element 1206, the second light-emitting element 1204, and the third light-emitting element 1202 may be less than a thickness of the submounts 1209a-1209c.

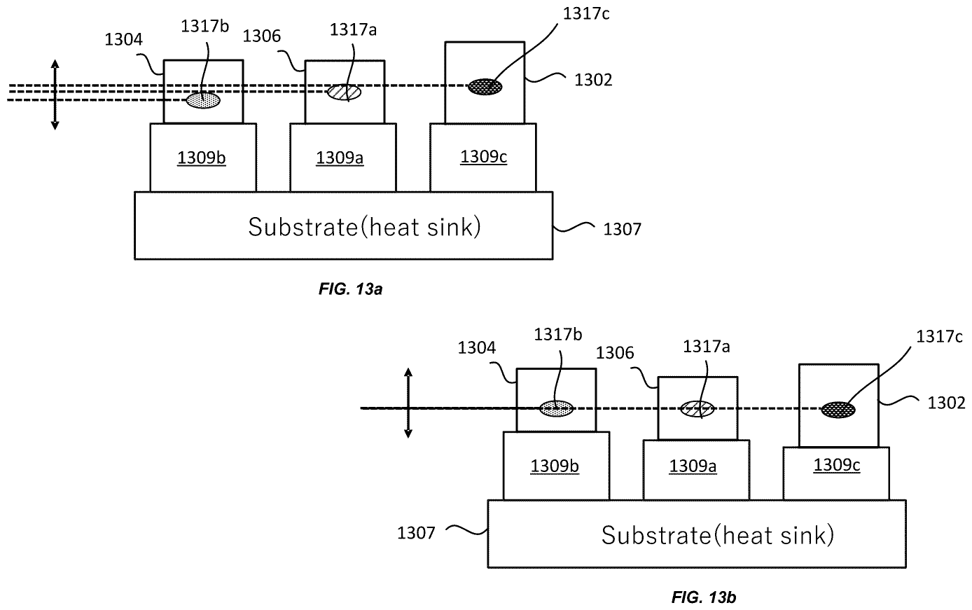

FIGS. 13a-13b provide simplified cross sectional depictions of RGB devices in accordance with some embodiments. FIG. 13a shows an example where a first light-emitting portion 1317a of a first light-emitting element 1306, a second light-emitting portion 1317b of a second light-emitting element 1304, and a third light-emitting portion 1317c of a third light-emitting element 1302 are located at different heights in a thickness direction. In some embodiments, the different heights may be caused at least in part by different thicknesses of p-type semiconductor layers in the different light-emitting elements.

FIG. 13b shows an example where the first light-emitting portion 1317a of the first light-emitting element 1306, the second light-emitting portion 1317b of the second light-emitting element 1304, and the third light-emitting portion 1317c of the third light-emitting element 1302 are located at approximately a same height in the thickness direction. In this example, the same height is obtained by varying a thickness of one or more of submounts 1309a-1309c. In some embodiments, the same height may be obtained by varying thickness of other layers of the light-emitting elements 1302-1306 while keeping the thickness of the submounts 1309a-1309c the same.

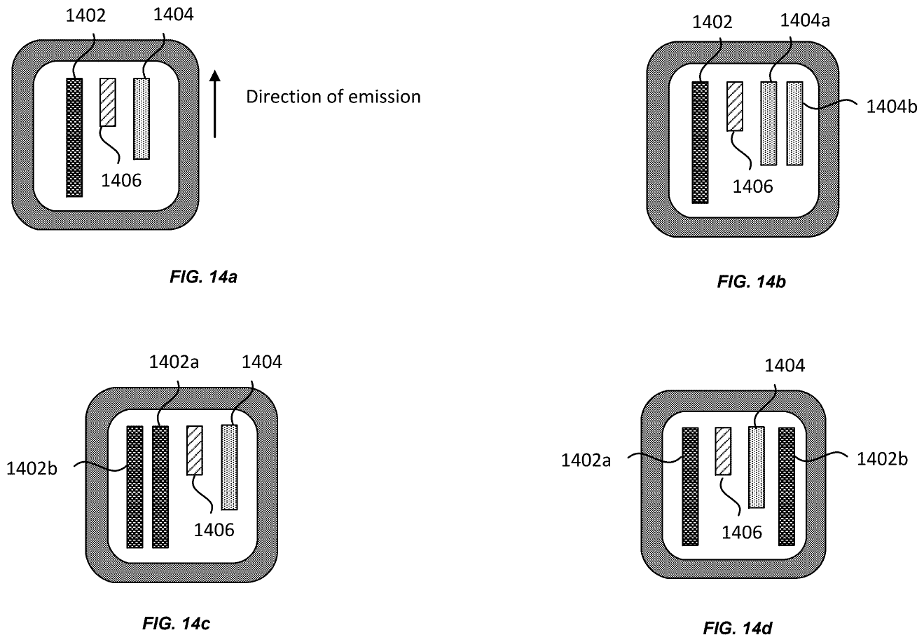

FIGS. 14a-14d provide simplified top view depictions of RGB packages in accordance with some embodiments. FIG. 14a shows an example where a length (or a dimension in a direction of emission) of the light-emitting elements increases in order from a first light-emitting element 1406, a second light-emitting element 1404, and a third light-emitting element 1402.

FIG. 14b shows an example that includes multiple second light-emitting elements 1404a-1404b, and FIG. 14c shows an example that includes multiple third light-emitting elements 1402a-1402b. Note that while FIG. 14b only shows two of the second light-emitting elements 1404a-1404b, and FIG. 14c only shows two of the third light-emitting elements 1404a-1404b, some embodiments may include more than two of the same kind of light-emitting elements. The plurality of light-emitting elements of the same kind may be electrically coupled in series with each other.

FIG. 14d shows an example that includes multiple third light-emitting elements 1402a-1402b. The first light-emitting element 1406 is positioned between the two third light-emitting elements 1402a-1402b. Other embodiments may include multiple second light-emitting elements, where the first light-emitting element 1406 is positioned between them.

Other embodiments and configurations may be used by those skilled in the art.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

The above description of exemplary embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated.

A recitation of “a”, “an”, or “the” is intended to mean “one or more” unless specifically indicated to the contrary.

All patents, patent applications, publications, and descriptions mentioned here are incorporated by reference in their entirety for all purposes. None is admitted to be prior art.

1. A light-emitting module, comprising:
a substrate;
a first light-emitting element located on the substrate and having a first wavelength;
a second light-emitting element located on the substrate and having a second wavelength longer than the first wavelength; and
a third light-emitting element located on the substrate and having a third wavelength longer than the second wavelength,
wherein the first light-emitting element is located on the substrate between the second light-emitting element and the third light-emitting element.

2. (canceled)

3. The light-emitting module according to claim 1, wherein a light-emitting surface of the third light-emitting element is positioned differently from a light-emitting surface of the first light-emitting element or the second light-emitting element in a light emission direction.

4. The light-emitting module according to claim 1, wherein a distance between the third light-emitting element and the first light-emitting element is greater than a distance between the first light-emitting element and the second light-emitting element.

5. The light-emitting module according to claim 1, wherein the third light-emitting element is longer than the first light-emitting element and the second light-emitting element.

6. The light-emitting module according to claim 1, wherein the first light-emitting element and the second light-emitting element further include an n-type semiconductor layer, an active layer, and a p-type semiconductor layer, and the p-type semiconductor layer is positioned closer to the substrate than the n-type semiconductor layer.

7. The light-emitting module according to claim 6, wherein the third light-emitting element further includes an n-type semiconductor layer, an active layer, and a p-type semiconductor layer, and the p-type semiconductor layer is positioned closer to the substrate than the n-type semiconductor layer.

8. The light-emitting module according to claim 6, wherein the third light-emitting element further includes an n-type semiconductor layer, an active layer, and a p-type semiconductor layer, and the n-type semiconductor layer is positioned closer to the substrate than the p-type semiconductor layer.

9. The light-emitting module according to claim 6, further comprising a package having electrodes to which the substrate is fixed, wherein wire bonding directly connects the electrodes to n-type semiconductor layers of the first light-emitting element and the second light-emitting element.

10. The light-emitting module according to claim 1, wherein a thickness of the third light-emitting element is different from a thickness of the first light-emitting element or the second light-emitting element.

11. The light-emitting module according to claim 1, wherein the first light-emitting element, the second light-emitting element, and the third light-emitting element are respectively positioned on submount substrates, and thicknesses of the first light-emitting element, the second light-emitting element, and the third light-emitting element are smaller than a thickness of the submount substrates.

12. The light-emitting module according to claim 1, wherein light-emitting portions of the first light-emitting element, the second light-emitting element, and the third light-emitting element are located at different positions in a thickness direction.

13. The light-emitting module according to claim 1, wherein the first light-emitting element, the second light-emitting element, and the third light-emitting element are positioned on submount substrates, and the submount substrates have different thicknesses.

14. The light-emitting module according to claim 1, wherein dimensions along a light-emitting direction increase in order from the first light-emitting element, the second light-emitting element, to the third light-emitting element.

15. The light-emitting module according to claim 1, wherein the second light-emitting element or the third light-emitting element comprises a plurality of light-emitting elements.

16. The light-emitting module according to claim 15, wherein the plurality of the second light-emitting elements or the plurality of the third light-emitting elements are electrically connected in series with each other.

17. The light-emitting module according to claim 16, wherein the first light-emitting element is positioned between at least two of the plurality of the second light-emitting elements or the plurality of the third light-emitting elements.

18. The light-emitting module according to claim 1, further comprising:
a base made of an electrically conductive material, on which the first light-emitting element, the second light-emitting element, and the third light-emitting element are disposed; and
a package disposed around the base.

19. (canceled)

20. The light-emitting module according to claim 18, wherein an upper surface of the base on which the first light-emitting element, the second light-emitting element, and the third light-emitting element are disposed is positioned higher than an upper surface of the package.

21. (canceled)

22. A light-emitting module, comprising:
a substrate;
a first light-emitting element located on the substrate and having a first wavelength;
a second light-emitting element located on the substrate and having a second wavelength longer than the first wavelength; and
a third light-emitting element located on the substrate and having a third wavelength longer than the second wavelength,
wherein the first light-emitting element and the second light-emitting element further include an n-type semiconductor layer, an active layer, and a p-type semiconductor layer, and the p-type semiconductor layer is positioned closer to the substrate than the n-type semiconductor layer.

23. A light-emitting module, comprising:
a substrate;
a first light-emitting element located on the substrate and having a first wavelength;
a second light-emitting element located on the substrate and having a second wavelength longer than the first wavelength; and
a third light-emitting element located on the substrate and having a third wavelength longer than the second wavelength,
wherein the first light-emitting element and the second light-emitting element are located on a first carrier, and the third light-emitting element is located on a second carrier different from the first carrier.
